(19) United States
(12) Patent Application Publication
(10) Pub. No.: US 2010/0190430 A1
(43) Pub. Date: Jul. 29, 2010

(54) AIR PERMEABLE MATERIAL FOR DATA CENTER COOLING

(75) Inventors: Jean-Michel Rodriguez, Montpellier (FR); Isabelle Ferrand, Mauguio (FR)

Correspondence Address: SCULLY, SCOTT, MURPHY & PRESSER, P.C., 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 12/400,117

(22) Filed: Mar. 9, 2009

(30) Foreign Application Priority Data
Jan. 29, 2009 (FR) EP09305080.5

(51) Int. Cl. H05K 5/00

(52) U.S. Cl. 454/184

(57) ABSTRACT

An arrangement for the controllable cooling of a data center, and more particularly, pertains to an arrangement for the provision of an improved computer room air-conditioning system (CRACS), which utilizes the installation of equipment above a raised floor and enables cooling air to be controllably dispensed through ducting installed below the computer installations. Also provided is a method for the controllable cooling of data center installations.

### BACKGROUND OF THE INVENTION

1. Field of the Invention

The present invention relates to an arrangement for the cooling of a data center, and more particularly, pertains to an arrangement for the provision of an improved computer room air-conditioning system (CRACS), which utilizes the installation of equipment above a raised floor and enables cooling air to be controllably dispensed from below the computer installations. Moreover, the invention also provides for a method for the controllable cooling of data center installations.

The installation of air cooling systems for large-sized data centers, which house pluralities of computer devices, such as servers, in computer racks which are positioned on a raised floor and leave cold and hot aisles for flows of air between various racks containing the computer equipment, is well-known in the current technology. In particular, the raised floor provides for a space facilitating circulation of cooling air beneath the computer equipment or racks, and frequently incorporates perforated tiles which enable the cooling air flow to rise upwardly into the cold aisles between the various computer racks, and whereby the hot aisles enable heated air to return and to be conducted into a return air plenum for cooling and recycling through the data center.

Although the flow of the cooling air, which is conveyed upwardly through the perforated tiles into the cold aisles between the racks for the computer equipment of the data center, is ordinarily considered to be satisfactory in its functioning upon occasion, there is encountered an unequal distribution of the flow of cold air into some of the cold aisles, so as to result in an unsatisfactorily adequate degree of cooling of at least some of the computer equipment. Moreover, due to the ever-increasing utilization of high density computer racks containing blade servers and other heat-generating data equipment, the cooling requirements of such data centers and computer rooms have rapidly increased and wherein the underfloor cooling systems in which cooling air that is circulated beneath the raised floors is commonly employed. However, as indicated, due to the large scale of present data centers, so-called “hot spots” are frequently encountered in the areas beneath the cold aisles of various computer racks, and consequently, it becomes necessary to balance the cooling air flow in the space beneath the computer room or data center so that generally a uniform degree or amount of cooling air is conveyed upwardly into each of the various cold aisles between the computer equipment racks so as to uniformly cool the equipment contained therein.

2. Discussion of the Prior Art

Although pipes, tubes or ducting has been employed in the space within the confines of the raised floor, in essence, beneath the level of the computer racks and equipment, in order to guide the cooling air flow within specified ducting or channels, the controlled directioning of the cooling air by means of either pipes, tubes or ducting causes the air flowing therethrough to be substantially compressed and, resultingly, heated to undesirable temperatures. In dependence upon the ducting, tube or pipe sizes, the flow is congested and the air excessively pressurized, again raising the temperature of the cooling air, so as to render the air less efficient or even unusable in various locales of the data center beneath the computer equipment racks. Hereby, the concept of utilizing underfloor air conditioning systems for data center or computer room air-conditioners is well known in the technology and, per se, i.e., widely employed in the computer industry.

Bash, et al., U.S. Pat. No. 6,694,759 B1, disclose a cooling air circulation system, wherein computer equipment is supported on a raised floor, and in which the flow of cooling air therebeneath is monitored so as to control the pressures reigning therein predicated upon a reading of pressure sensors positioned at various locales. This concept enables the pressure in the cooling fluid to be controlled, however, it requires the installation of a relatively complex pressure sensing and monitoring system for controlling vents in order to maintain the pressures at viable levels. Moreover, a system of that type also necessitates the expenditures of large amounts of energy or electrical power for the operation thereof.

Other systems for conveying cooling air for computer racks or installations, which are positioned on a raised floor in a data center or computer room are disclosed in Chu, et al., U.S. Pat. No. 6,819,563 B1, Chu, et al., U.S. Pat. No. 6,967,841 B1 and Chu, et al., U.S. Patent Publication No. 2006/0232945 A1, all of which are commonly assigned to the assignee of the present application, and the disclosures of which are incorporated herein by reference.

Moreover, still further cooling devices and systems for the cooling of electronic assemblies that are supported on raised floors which permit for the flow of cooling air upwardly therethrough, are disclosed in Heitzig, U.S. Pat. No. 4,612,979; Bash, et al., U.S. Pat. No. 7,170,745 B2; Bettridge, et al., U.S. Pat. No. 7,226,353 B2; and Germagian, et al., U.S. Patent Publication No. 2006/0139877 A1.

Moreover, the concept of providing raised floors, which incorporate air conditioning to cool computer equipment stored thereabove by means of air flows, such as are adapted to pass through perforated floor tiles, is also extensively discussed, among other publications in the article by Roger R. Schmidt, et al., “Measurements and Predictions of the Flow Distribution Through Perforated Tiles in Raised-Floor Data Centers”, Proceedings of IPACK/01, Pages 905-914, ASME, 2001.

A further extensive article relating to such cooling systems for the air cooling of high-performance data centers, is disclosed in the January 2006 Design Guideline Source Book, entitled “High Performance Data Centers”, published by the Pacific Gas and Electric Company.

Although these publications each generally, and in various instances, quite specifically describe the air cooling of high performance data centers containing computer equipment and servers contained in storage racks, by circulating cooling air beneath and then upwardly through the raised floors on which the equipment is supported, none of these references provide for a simple structure which will enable a controlled distribution of cooling air in the space beneath the raised floor supporting the electronic equipment, which will prevent any excess pressurization or heating of cooling air to undesirable temperatures, while concurrently affording a uniform distribution of cooling air to the various cold aisles that are present between racks of the computer equipment.

### SUMMARY OF THE INVENTION

Accordingly, pursuant to a specific embodiment of the invention, there is provided ducting in the space beneath a raised floor of the aisles on which the electronic equipment is installed, whereby ducting comprises wall structure channeling the normally pressurized cooling air flow beneath the floor along desirable paths to provide for uniform distribution of cooling air into the various cold aisles between the computer equipment, while concurrently at least surface portions of the walls of the ducting is constituted of an air permeable material or including calibrated pores, which will enable a certain amount of the air flow to be diverted outwardly through the ducting, so as to thereby provide for a balancing in the amount of air flow being conveyed beneath the raised floor within the confines of the ducting. This permeable structure will, per se, prevent any undue pressure build up within the ducting caused by the flow of cooling air and inhibit any excessive or under-pressurized conditions to be encountered therein. As a result, this surface permeability will afford a controlled flow and pressurization of the cooling air beneath the raised floor without having to undergo the expenditures of complex, expensive and energy consuming sensing and control systems for the venting of any excessively-pressurized air, as may be encountered in the state-of-the-art.

Pursuant to a modified embodiment of the invention, there is provided a ducting structure for guiding the cooling air flow in a space beneath the raised floor, wherein rather than air-permeable wall surfaces, flap valves may be formed in the side walls of the ducting which, upon the pressure of the cooling air flowing within the ducting exceeding a specified limit, will deflect the flaps, preferably outwardly into open positions, thereby causing the venting of at least some of the air, thereby enabling the air flow to be expanded within the ducting and concurrently reducing any air pressure reigning therein to tenable levels.

Accordingly, it is an object of the present invention to provide conduits or ducting in a space beneath a raised floor supporting or mounting electronic or data equipment, which incorporates wall surfaces constituted of an air-permeable, or porous material having calibrated pores which will enable maintaining optimum air pressures in the ducting for the distribution of cooling air, preventing over-pressurization of air and any temperature rise caused by the resultant pressure increase encountered in the air flow.

Pursuant to a modified embodiment of the present invention, the conduits or ducting may comprise a plurality of outlet valves, such as simple flap valves or the like, which will effect a pressure relief from excessive air pressures so as to maintain an optimum pressure within the ducting for the distribution of cooling air, while preventing any heating of the air caused by an excessive pressure increase or over-pressurized air being conveyed therethrough.

Pursuant to a further modification, it is an object of the present invention to provide relief pressures by the valves which are formed in the surface of the ducting to be varied along the length of the ducting in order to provide for suitable pressure gradients throughout the air cooling flow system beneath the raised floor, which system comprises a plurality of such ducting or conduits forming a flow network.

### BRIEF DESCRIPTION OF THE DRAWINGS

Reference may now be made to the following detailed description of preferred embodiments of the invention, taken in conjunction with the accompanying drawings, in which:

FIG. 1 illustrates, generally diagrammatically, a datacenter including a typical hot aisle and cold aisle arrangement for computer racks containing electronic equipment, wherein the data center incorporates a raised floor and a circulating air-cooling system;

FIG. 2 illustrates, generally schematically, a portion of a raised floor arrangement for the data center showing the cooling air flow in the absence of air flow guiding ducting;

FIG. 3 illustrates, generally schematically, ducting arranged beneath a raised floor of the data center, wherein the ducting may be part of an entire network of ducting for directing cooling air flow to various cold aisles between computer equipment racks that are positioned thereabove;

FIG. 4 illustrates a section of ducting similar to that of FIG. 3, incorporating side walls of an air permeable material or porous structure to enable an outward flow of cooling air therethrough for reducing pressures reigning in the ducting;

FIG. 5 illustrates another embodiment of the ducting side wall, incorporating a plurality of pressure venting valves;

FIG. 6 includes an enlarged fragmentary portion of the side wall structure of the ducting of FIG. 5 indicating the direction of pressure-relieving air flow passing through the opened venting valve; and

FIGS. 7 through 9 each illustrates, diagrammatically, theoretical pressure distributions in the ducting responsive to a cooling air flow passing therethrough.

### DETAILED DESCRIPTION OF THE INVENTION

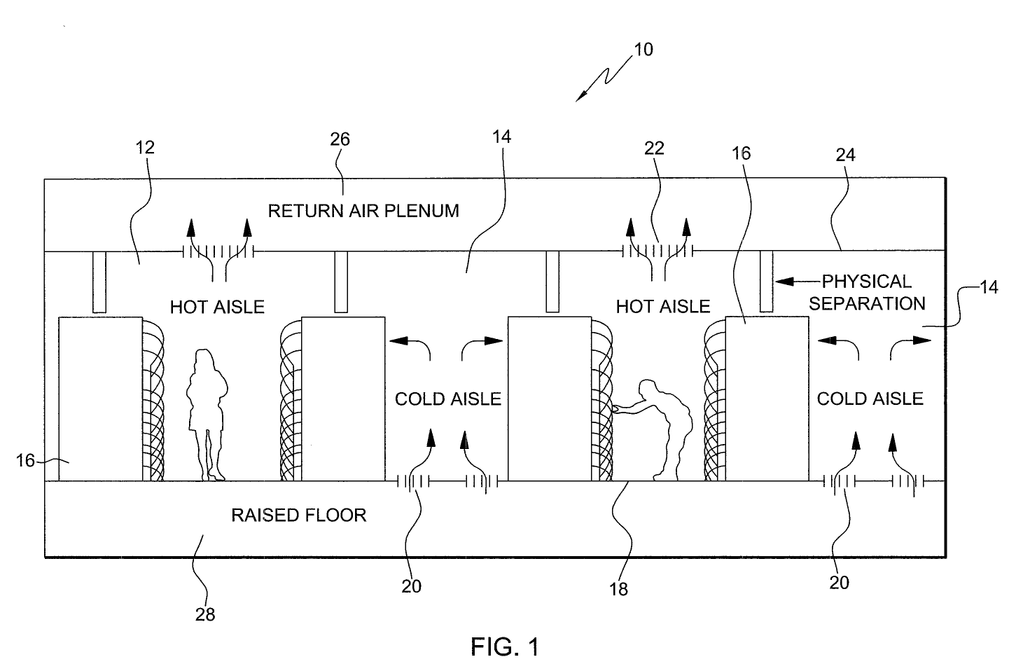

Referring to FIG. 1, there is illustrated diagrammatically, a high performance data center 10 with a hot aisle 12 and cold air aisle 14 arrangement for computer or electronic equipment racks 16, the latter of which are arranged and supported on a raised floor 18 which has flows of cooling air passing upwardly therethrough for cooling the equipment in the racks 16. In particular, the raised floor 18 has perforated tiles 20 which communicate with the cold aisles 14 between the racks 16 to enable cold air to rise upwardly and pass through the equipment into the hot aisles 12, which enables the hot air to rise upwardly through openings 22 in a ceiling 24 and into a return air plenum 26 for cooling and recycling the heated air.

In general, the structure of the raised floor 18, as illustrated in FIG. 1, is well-known in the technology and comprises part of the data center 10, wherein the equipment in the racks 16 is cooled through a forced air circulation. However, at various times, the cooling air, which is conducted through the space 28 below the raised floor 18, is distributed in an unequal or unbalanced manner, whereby some of the perforated tiles 20 communicating with the cold aisles 14 receive insufficient amounts of cooling air flows, whereby the equipment located within those aisles is inadequately cooled, whereas other cold aisles may receive an excess of cooling air.

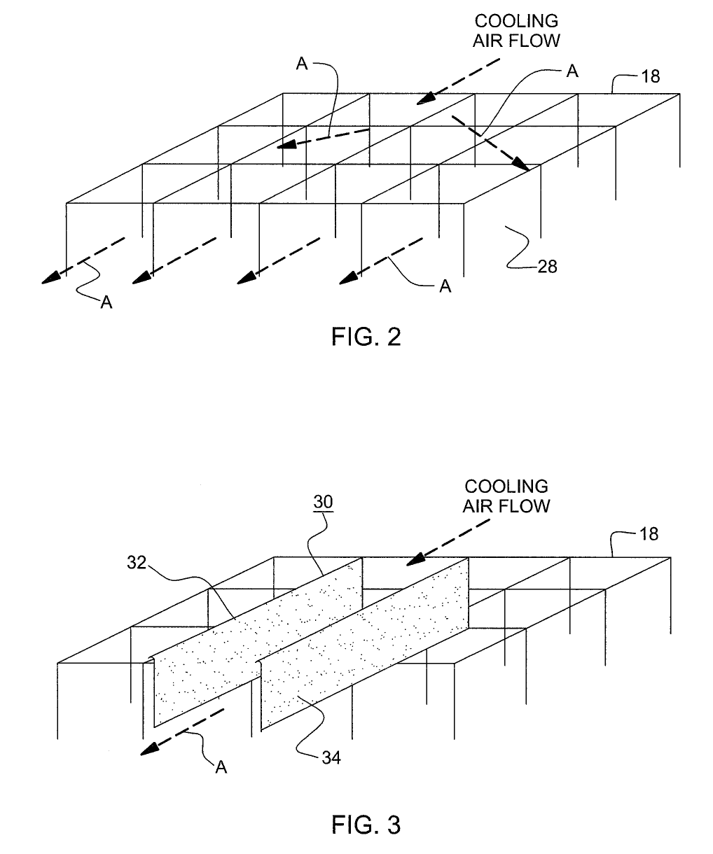

In essence, as shown in a diagrammatic manner in FIG. 2 of the drawings, wherein the space 28 below the raised floor 18 is represented, the arrows A indicate the essentially random flows of cooling air, which, as can be ascertained, may be unequally distributed to various cold aisles 14, so as to provide for an unequal and unbalanced amount of cooling air being circulated through the data center 10.

In order to provide for a more uniform air distribution, pursuant to the prior art, there may be provided a system of ducting or conduits 30, as illustrated in FIG. 3 of the drawings, in a partial representation, whereby a network of such ducting 30 comprises side walls 32, 34 that circulates or guides the cooling air flow within the space 28 beneath the raised floor 18, so as to essentially ensure that equal or balanced amounts of cooling air are conducted towards the various perforated tiles beneath the respective cold aisles between the electronic equipment racks located above the raised floor.

Although the foregoing arrangement of ducting 30 provides for a channeling of air flow so as to provide a more uniform distribution of the cooling air in the space 28 beneath the raised floor 18, at times the cooling air flow is over compressed or excessively pressurized so as to cause the cooling air to be heated at various locations and to, resultingly, impair the efficiency of the air employed for cooling for the various equipment racks due to the over-pressurizing of the air.

Moreover, the air due to the possible excessive pressurization thereof, may at times becomes compressed within the conduits or ducting 30, again further raising the temperature of the air to undesirable levels and thereby reducing the efficacy in the cooling of the rack equipment 16 arranged in the data center 10.

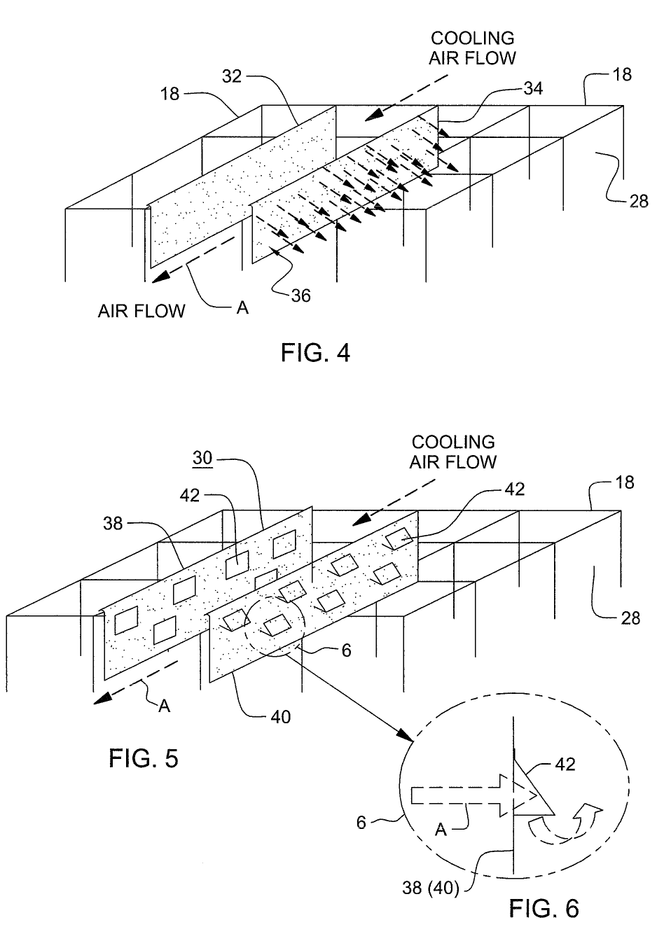

Accordingly, in order to improve the foregoing in a unique and novel manner pursuant to the invention, in one embodiment, as disclosed in FIG. 4 of the drawings, at least some side wall portions 36 of the conduits 30 of the network or system of conduits may be constituted of wall segments consisting of an air-permeable material or formed with porous surface sections of predetermined pore sizes, which enable at least part of the pressurized cooling air to egress outwardly through the conduit side wall or walls 36, so as to lower any pressure reigning therein to acceptable levels and thereby maintain the cooling efficacy of the air flow by essentially a lowering of the pressure and resultant air temperatures.

Pursuant to a further embodiment of the present invention, as illustrated in FIGS. 5 and 6 of the drawings, the side walls 38, 40 of at least portions of the ducting 30 of the ducting network, which is arranged in the space 28 beneath the raised floor 18 may be provided with pressure relief valves 42 or vents, preferably in a form of outwardly deflecting flap valves that are formed in the side walls, whereby any excessive or over-pressure in the air flow reigning within the ducting 30 will cause at least some of the valves 42 to deflect outwardly into opening positions so as to enable portions of the excessively-pressurized air to flow outwardly therethrough from interiorly of the ducting, so as to reduce the pressure within the ducting and the concurrently balanced air flow being conveyed towards and through the perforated tiles 20 communicating with the cold aisles 14 to tenable levels.

The valves 42, as mentioned, may be comprised of simple flap valves that are formed or mounted in the side wall structure 38, 40 of the ducting or conduits 30, and may be calibrated along the lengths of the aisles so as to open within predetermined pressure-responsive ranges depending upon the reigning excessive pressures being encountered at various locales within the ducting.

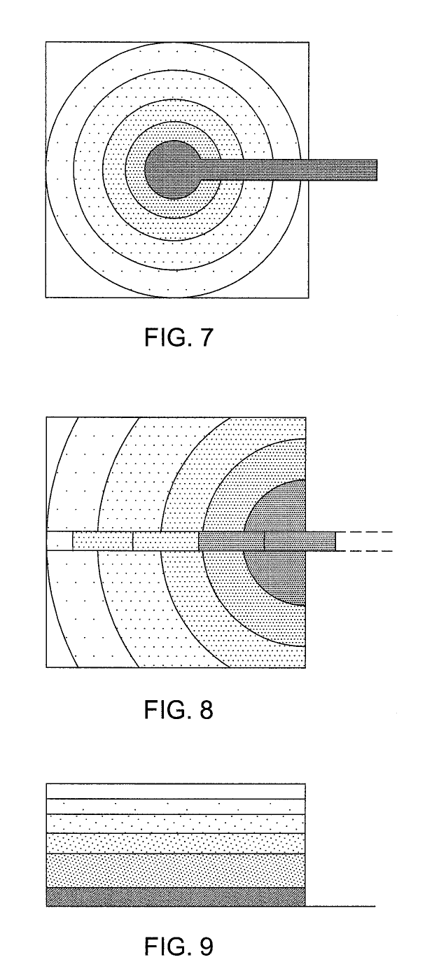

As illustrated in FIG. 7 of the drawings, this graphically shows the pressure distribution within the ducting, and theoretically represents a pressure distribution, which may be produced by a simple conduit opening into an open space.

FIG. 8, in turn, graphically represents the pressure distribution acting upon the side walls of the conduit being either perforated or opened.

Finally, FIG. 9 graphically represents a distribution which may be achieved by having an increasingly porous or pore-sized conduit present along the length of the ducting, or a variably calibrated valve structure incorporated into the conduit wall.

From the foregoing, it becomes clearly evident that by incorporating pressure-relieving properties into the ducting 30 beneath a raised floor 18 in an air cooled data center 14 of the type described herein, that this enables the cooling efficacy of the air flow to be maintained within desired levels, while facilitating control thereover in a simple and inexpensive manner in the absence of any energy requiring devices or sensors having to be employed therein.

While it is apparent that the invention herein disclosed is well calculated to fulfill the objects stated above, it will be appreciated that numerous modifications and embodiments may be devised by those skilled n the art, and it is intended that the appended claims cover all such modifications and embodiments as fall within the true spirit and scope of the present invention.

What is claimed is:

1. An arrangement for cooling electronic components by a flow of cooling air that is conveyed from a space beneath a raised apertured floor on which said electronic components are supported, said arrangement comprising:
ducting structure arranged in said space for conducting said flow of air through said space for a distribution within said space and conveyance through said floor apertures into cooling regions communicating with said electronic components, said ducting structure including side walls forming guiding means for said flow of air, at least one of said side walls having at least one air-permeable surface portion enabling the covers of portions of said flow of air from said ducting structure in order to controllably relieve any build-up of excessive air pressure therein potentially causing an uneven distribution of cooling air to at least one or more of said electronic components.

2. An arrangement as claimed in claim 1, wherein said air-permeable surface portion of said at least one side wall is constituted of a porous material.

3. An arrangement as claimed in claim 1, wherein said air-permeable surface portion of said at least one side wall comprises a plurality of pores formed in said at least one surface portion.

4. An arrangement as claimed in claim 3, wherein said pores are distributed and calibrated in a predetermined pattern along the extent of said at least one air-permeable surface portion.

5. An arrangement as claimed in claim 1, wherein said at least one said side wall comprises a plurality of pressure-relief valves formed therein, said valves being opened in the presence of an excessive pressure reigning in said ducting caused by the flow of air so as to enable the egress through said valves of portions of said air flow to resultingly reduce the pressure reigning in said ducting to tenable levels.

6. An arrangement as claimed in claim 5, wherein said valves are calibrated to open along the extent of said at least one ducting side wall responsive to varying levels of excessive pressures reigning in said ducting.

7. An arrangement as claimed in claim 5, wherein said valves are flap valves pivotably attached to said at least one ducting side wall.

8. An arrangement as claimed in claim 1, wherein said at least one air-permeable surface portion of said at least one ducting side wall enables the egress of excessively-pressurized cooling air from said ducting so as to inhibit any rise in the cooling air temperature tending to reduce the efficacy of the cooling effect of said flow of cooling air from said space towards the electronic components.

9. An arrangement as claimed in claim 1, wherein said electronic components are contained in computer racks of a data center.

10. A method of cooling electronic components by a flow of cooling air that is conveyed from a space beneath a raised apertured floor on which said electronic components are supported, said method comprising:
arranging a ducting structure in said space for conducting said flow of air through said space for a distribution within said space and conveyance through said floor apertures into cooling regions communicating with said electronic components;
providing said ducting structure with side walls forming guiding means for said flow of air;
equipping at least one of said side walls with at least one air-permeable surface portion enabling the covers of portions of said flow of air from said ducting structure in order to controllably relieve any build-up of excessive air pressure therein potentially causing an uneven distribution of cooling air to at least one or more of said electronic components.

11. A method as claimed in claim 10, wherein said air-permeable surface portion of said at least one side wall is constituted of a porous material.

12. A method as claimed in claim 10, wherein said air-permeable surface portion of said at least one side wall comprises forming a plurality of pores in said at least one surface portion.

13. A method as claimed in claim 12, wherein said pores are distributed and calibrated in a predetermined pattern along the extent of said at least one air-permeable surface portion.

14. A method as claimed in claim 10, wherein said at least one said side wall comprises a plurality of pressure-relief valves formed therein, said valves being opened in the presence of an excessive pressure reigning in said ducting caused by the flow of air so as to enable the egress through said valves of portions of said air flow to resultingly reduce the pressure reigning in said ducting to tenable levels.

15. A method as claimed in claim 14, wherein said valves are calibrated to open along the extent of said at least one ducting side wall responsive to varying levels of excessive pressures reigning in said ducting.

16. A method as claimed in claim 15, wherein said valves are flap valves pivotably attached to said at least one ducting side wall.

17. A method as claimed in claim 10, wherein said at least one air-permeable surface portion of said at least one ducting side wall enables the egress of excessively-pressurized cooling air from said ducting so as to inhibit any rise in the cooling air temperature tending to reduce the efficacy of the cooling effect of said flow of cooling air from said space towards the electronic components.

18. A method as claimed in claim 10, wherein said electronic components are contained in computer racks of a data center.
